(19) United States
(12) Patent Application Publication
(10) Pub. No.: US 2014/0174792 A1
(43) Pub. Date: Jun. 26, 2014

(54) INSULATING FILM FOR PRINTED CIRCUIT BOARD HAVING IMPROVED THERMAL CONDUCTIVITY, MANUFACTURING METHOD THEREOF, AND PRINTED CIRCUIT BOARD USING THE SAME

(71) Applicant: SAMSUNG ELECTRO-MECHANICS CO., LTD., Suwon (KR)

(72) Inventors: Jang Bae Son, Suwon (KR); Joon Seok Kang, Suwon (KR); Sang Hyun Shin, Suwon (KR); Kwang Jik Lee, Suwon (KR); Hye Sook Shin, Suwon (KR); Hyun Chul Jung, Suwon (KR)

(73) Assignee: SAMSUNG ELECTRO-MECHANICS CO., LTD., Suwon (KR)

(21) Appl. No.: 13/845,831

(22) Filed: Mar. 18, 2013

(30) Foreign Application Priority Data
Dec. 24, 2012 (KR) 10-2012-0152064

(51) Int. Cl. H01B 3/30; H05K 1/02

(52) U.S. Cl. CPC H01B 3/305; H05K 1/0203
USPC 174/252; 525/423; 524/424

(57) ABSTRACT

This invention relates to an insulating film for a printed circuit board having improved thermal conductivity, a manufacturing method thereof and a printed circuit board using the same, wherein the insulating film includes an amphiphilic block copolymer having a vertical structure formed in a thickness direction by chemically coupling a hydrophilic compound with a hydrophobic compound.

### CROSS-REFERENCE TO RELATED APPLICATION

This application claims the benefit of Korean Patent Application No. 10-2012-0152064, filed Dec. 24, 2012, entitled “Insulating film for printed circuit board having improved thermal conductivity, producing method thereof, and printed circuit board using the same,” which is hereby incorporated by reference in its entirety into this application.

### BACKGROUND OF THE INVENTION

1. Technical Field

The present invention relates to an insulating film for a printed circuit board having improved thermal conductivity, a manufacturing method thereof, and a printed circuit board using the same.

2. Description of the Related Art

With the recent advancement of electronic devices and the demand for complicated functions thereof, printed circuit boards are being manufactured so as to be lighter, slimmer, and smaller. In order to fulfill such requirements, printed circuit wiring has become more complicated and even denser, and its functionality has increased.

As electronic devices are being manufactured so as to be small and to have high functionality, as mentioned above, a multilayer printed circuit board is required, which has high density and high functionality and becomes small and slim. In particular, the development of a multilayer printed circuit board is carried out so that its wiring becomes fine and dense. Accordingly, thermal, mechanical and electrical properties of an insulating layer of the multilayer printed circuit board are considered important. Particularly, in order to minimize warpage due to reflow in the course of mounting an electronic/electrical device, the device has to have a low coefficient of thermal expansion (CTE), a high glass transition temperature (Tg), and high modulus.

An insulating substrate for a printed circuit board is typically exemplified by a copper clad laminate obtained by incorporating a binder into reinforced glass fibers, drying it, thus obtaining a prepreg, laminating a predetermined number of prepregs, and layering a copper foil thereon. The prepreg is formed by impregnating glass fibers with a cross-linkable resin such as epoxy. However, in the case of the prepreg manufactured by the above method using general glass fibers, it is common to encounter problems such as deformation and disconnection due to high CTE, making it impossible to develop a high value-added prepreg.

Although a printed circuit board typically functions to connect a variety of electronic parts to a printed-circuit base board, depending on the circuit design of electrical wiring thereof, or to support the parts, power consumption of the parts is increased and a large quantity of heat is generated in proportion to an increase in the number of mounted passive parts and packages, and thus heat dissipation performance is regarded as important in terms of reliability of products and consumers' product preferences.

Meanwhile, as products are being manufactured to be smaller, although their functionality is improving, the generation of heat per unit volume increasing, and thus the emission of heat generated is becoming an issue.

In order to conventionally improve heat dissipation performance, the amount of a filler is increased. Furthermore, to increase thermal conductivity of the filler, as disclosed in Patent Literature 1, a printed circuit board is manufactured using an inorganic filler such as alumina, aluminum nitride, and boron nitride, and also, an insulating film having improved heat dissipation performance is manufactured using fillers having a variety of sizes to attain effective thermal conductivity.
Patent Literature 1: Korean Patent No. 10-1005242

### SUMMARY OF THE INVENTION

Culminating in the present invention, intensive and thorough research with the aim of solving the problems occurring in the related art resulted in the finding that an insulating film manufactured using an amphiphilic block copolymer which forms a vertical structure depending on the mole ratio of a hydrophilic compound and a hydrophobic compound may exhibit superior heat dissipation performance.

Accordingly, a first aspect of the present invention is to provide an insulating film for a printed circuit board having improved thermal conductivity.

A second aspect of the present invention is to provide a method of simply and economically manufacturing the insulating film.

A third aspect of the present invention is to provide a printed circuit board using the insulating film.

In order to accomplish the above first aspect of the present invention, an insulating film for a printed circuit board having superior heat dissipation performance (hereinafter, referred to as “the first invention”) is manufactured from a resin composition including an amphiphilic block copolymer having a vertical structure formed in a thickness direction by chemically coupling a hydrophilic compound with a hydrophobic compound.

In the first invention, the hydrophilic compound and the hydrophobic compound may be coupled at a mole ratio of 1.5˜4:1.

In the first invention, the hydrophilic compound may be an epoxy group-containing compound.

In the first invention, the hydrophobic compound may be a liquid crystal polymer.

In the first invention, the liquid crystal polymer may be represented by Chemical Formula 1, Chemical Formula 2, Chemical Formula 3, Chemical Formula 4 or Chemical Formula 5 below.

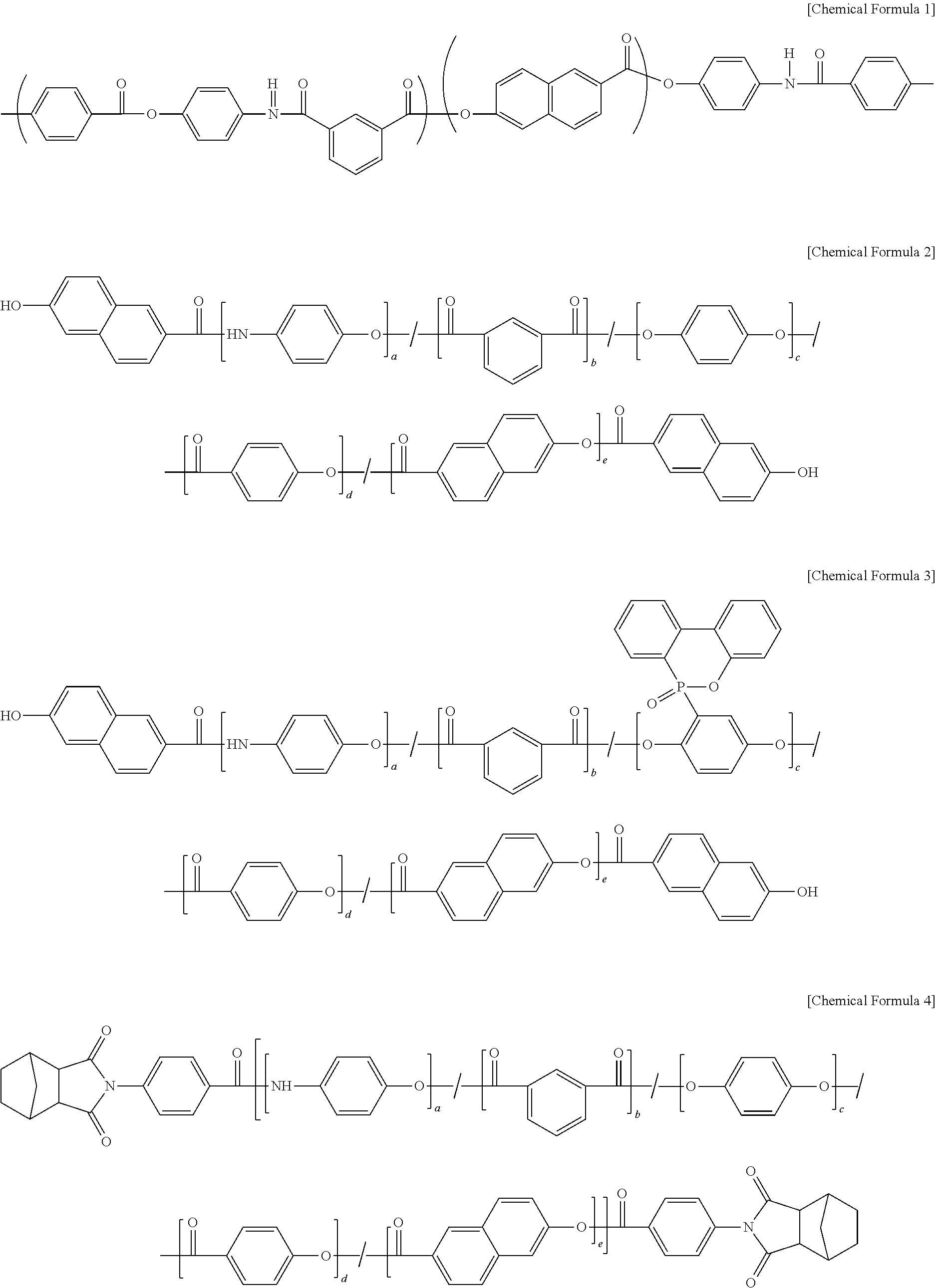

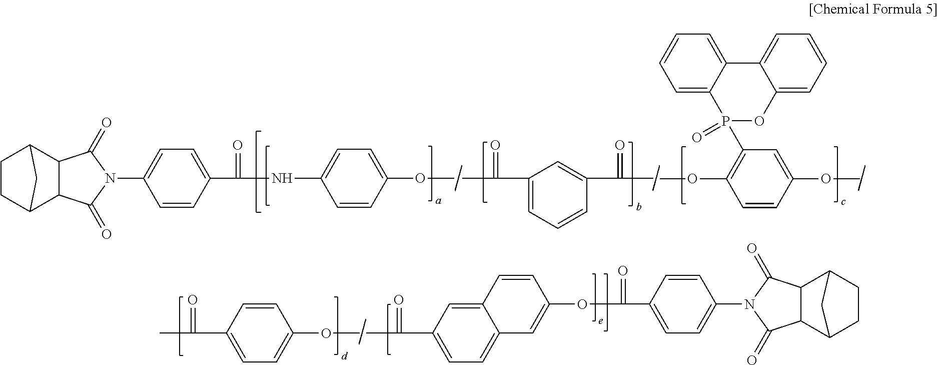

wherein a is an integer of 13˜26, b is an integer of 13˜26, c is an integer of 9˜21, d is an integer of 10˜30, and e is an integer of 10˜30.

In the first invention, the vertical structure may be a hexagonal structure or a cylinder structure.

In the first invention, the amphiphilic block copolymer may be a compound represented by Chemical Formula 6 below.

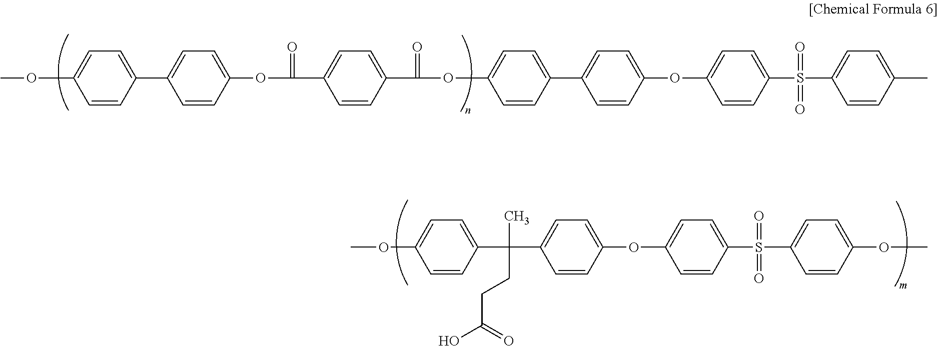

wherein n is an integer of 2˜12, and m is an integer of 6˜48.

In the first invention, the insulating film may further include an inorganic filler comprising one or more selected from the group consisting of silica, alumina, barium sulfate, talc, clay, mica powder, aluminum hydroxide, magnesium hydroxide, calcium carbonate, magnesium carbonate, magnesium oxide, boron nitride, aluminum nitride, aluminum borate, barium titanate, calcium titanate, magnesium titanate, bismuth titanate, titanium oxide, barium zirconate, and calcium zirconate.

In the first invention, the insulating film may further include an epoxy resin comprising one or more selected from the group consisting of a naphthalene-based epoxy resin, a bisphenol A type epoxy resin, a phenol novolac epoxy resin, a cresol novolac epoxy resin, a rubber modified epoxy resin, and a phosphorous epoxy resin.

In the first invention, the insulating film may further include a curing agent comprising one or more selected from the group consisting of an amide-based curing agent, a polyamine-based curing agent, an acid anhydride curing agent, a phenol novolac type curing agent, a polymercaptan curing agent, a tertiary amine curing agent, and an imidazole curing agent.

In the first invention, the insulating film may further include a curing accelerator comprising one or more selected from the group consisting of a metallic curing accelerator, an imidazole-based curing accelerator, and an amine-based curing accelerator.

In order to accomplish the above second aspect of the present invention, a method of manufacturing an insulating film (hereinafter, referred to as “the second invention”) includes dissolving a hydrophilic compound in a solvent thus providing a first solution, and dissolving a hydrophobic compound in a solvent, thus providing a second solution; mixing the first solution with the second solution so as to react, thus forming an amphiphilic block copolymer having a vertical structure formed in a thickness direction by chemically coupling the hydrophilic compound with the hydrophobic compound; recovering the amphiphilic block copolymer; and forming a film using the recovered amphiphilic block copolymer.

In the second invention, the vertical structure may be a hexagonal structure or a cylinder structure.

In the second invention, the amphiphilic block copolymer may be a compound represented by Chemical Formula 6 below.

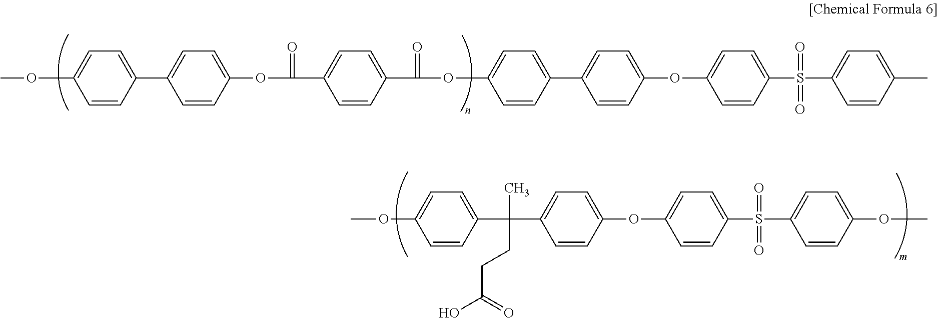

wherein n is an integer of 2˜12, and m is an integer of 6˜48.

In the second invention, the hydrophilic compound and the hydrophobic compound may be coupled at a mole ratio of 1.5˜4:1.

In the second invention, the hydrophilic compound may be an epoxy group-containing compound.

In the second invention, the hydrophobic compound may be a liquid crystal polymer.

In order to accomplish the above third aspect of the present invention, a printed circuit board is manufactured using the first invention.

### BRIEF DESCRIPTION OF THE DRAWINGS

The above and other aspects, features and other advantages of the present invention will be more clearly understood from the following detailed description when taken in conjunction with the accompanying drawings, in which:

FIG. 1 is a cross-sectional view illustrating a typical printed circuit board to which an insulating film according to the present invention may be applied; and

FIG. 2 is a flowchart illustrating a process of manufacturing the insulating film according to the present invention.

### DESCRIPTION OF SPECIFIC EMBODIMENTS

Before the present invention is described in more detail, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention. It is noted that, the embodiments of the present invention are merely illustrative, and are not construed to limit the scope of the present invention, and thus there may be a variety of equivalents and modifications able to substitute for them at the point of time of the present application.

In the following description, it is to be noted that embodiments of the present invention are described in detail so that the present invention may be easily performed by those skilled in the art, and also that, when known techniques related with the present invention may make the gist of the present invention unclear, a detailed description thereof will be omitted.

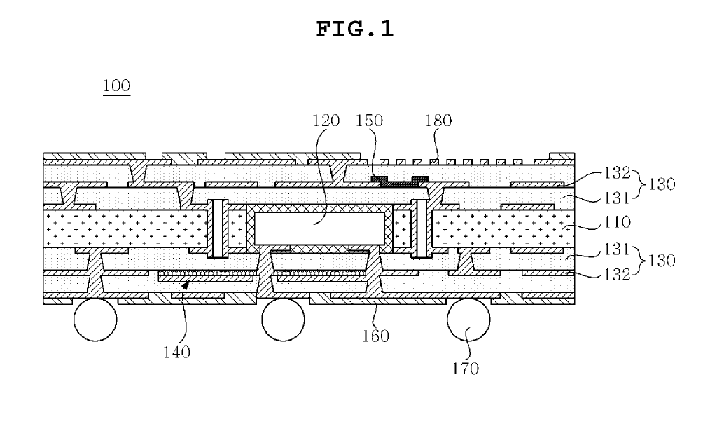

FIG. 1 is a cross-sectional view illustrating a typical printed circuit board to which a resin composition according to the present invention may be applied. As illustrated in FIG. 1, a printed circuit board 100 may be an embedded board including electronic parts therein. Specifically, the printed circuit board 100 may include an insulator or prepreg 110 having a cavity, an electronic part 120 provided in the cavity, and build-up layers 130 formed on one or more of the upper and lower surfaces of the insulator or prepreg 110 including the electronic part 120. The build-up layers 130 may include insulating layers 131 formed on one or more of the upper and lower surfaces of the insulator 110, and circuit layers 132 which are formed on the insulating layers 131 and may achieve interlayer connection.

An example of the electronic part 120 may include an active device such as a semiconductor device. Also, the printed circuit board 100 may further include one or more additional electronic parts, for example, a capacitor 140, a resistor 150, etc., in addition to the single electronic part 120. In embodiments of the present invention, the kind or number of the electronic parts is not limited. As such, the insulator or prepreg 110 and the insulating layers 131 play a role in imparting insulating properties between the circuit layers or between the electronic parts, and also function as a support for maintaining rigidity of a package.

In the case where the wiring density of the printed circuit board 100 is increased, to decrease noise between the circuit layers and also to reduce parasitic capacitance, the insulator or prepreg 110 and the insulating layers 131 should have low dielectric properties. Furthermore, the insulator or prepreg 110 and the insulating layers 131 should have low dielectric loss to increase insulating properties.

At least any one of the insulator or prepreg 110 and the insulating layers 131 is particularly useful so long as it has superior heat resistance and mechanical strength as well as improved heat dissipation properties.

In order to manufacture the insulating film having improved heat dissipation properties, an amphiphilic block copolymer which forms a vertical structure is employed. The amphiphilic block copolymer is a polymer compound obtained by chemically coupling a hydrophilic compound with a hydrophobic compound, and physical chemical properties of the amphiphilic block copolymer may be variously controlled by adjusting the repeating units of the hydrophilic compound and the hydrophobic compound. An amphiphilic block copolymer may be generally utilized in a drug delivery system, a template for forming a metal nanostructure, etc.

In the present invention, the amphiphilic block copolymer is applied to the insulating film of the printed circuit board because it may form a specific structure. The amphiphilic block copolymer having a vertical structure such as a hexagonal structure or a cylinder structure is formed by adjusting the mole ratio of the hydrophilic compound and the hydrophobic compound, so that heat generated from the printed circuit board is effectively transferred in a vertical direction and is thus dissipated.

Heat generated from the printed circuit board is typically emitted using the inorganic filler of the insulating film, but limitations are imposed on setting the amount of the inorganic filler. Because the filler is expensive, heat dissipation performance of the resin has to be improved in order to economically emit heat. Hence, when the amphiphilic block copolymer is used in this way, it is possible to control the stereostructure of the copolymer, and thus heat is effectively transferred in a desired direction via the control of the steric arrangement of the resin composition of the insulating film, making it possible to improve heat dissipation performance.

In the present invention, the hydrophilic compound and the hydrophobic compound react at a mole ratio of 1.5˜4:1. If the mole ratio of the hydrophilic compound is less than 1.5 or exceeds 4, a vertical structure as desired in the present invention cannot be formed.

According to the present invention, the hydrophilic compound may include diphenolic acid, 4,4′-dichlorodiphenylsulfone, an epoxy group-containing compound, or mixtures thereof. Particularly useful is an epoxy group-containing compound. Examples of the epoxy group-containing compound include, but are not necessarily limited to, a naphthalene-based epoxy resin, a bisphenol A type epoxy resin, a phenol novolac epoxy resin, a cresol novolac epoxy resin, a rubber modified epoxy resin, a phosphorous epoxy resin, and mixtures thereof.

The hydrophobic compound may be a liquid crystal polymer. When the liquid crystal polymer is used as the hydrophobic compound, heat dissipation performance according to the present invention may be further improved because of heat dissipation properties of the liquid crystal polymer. The liquid crystal polymer may be represented by Chemical Formulas 1 to 5 below.

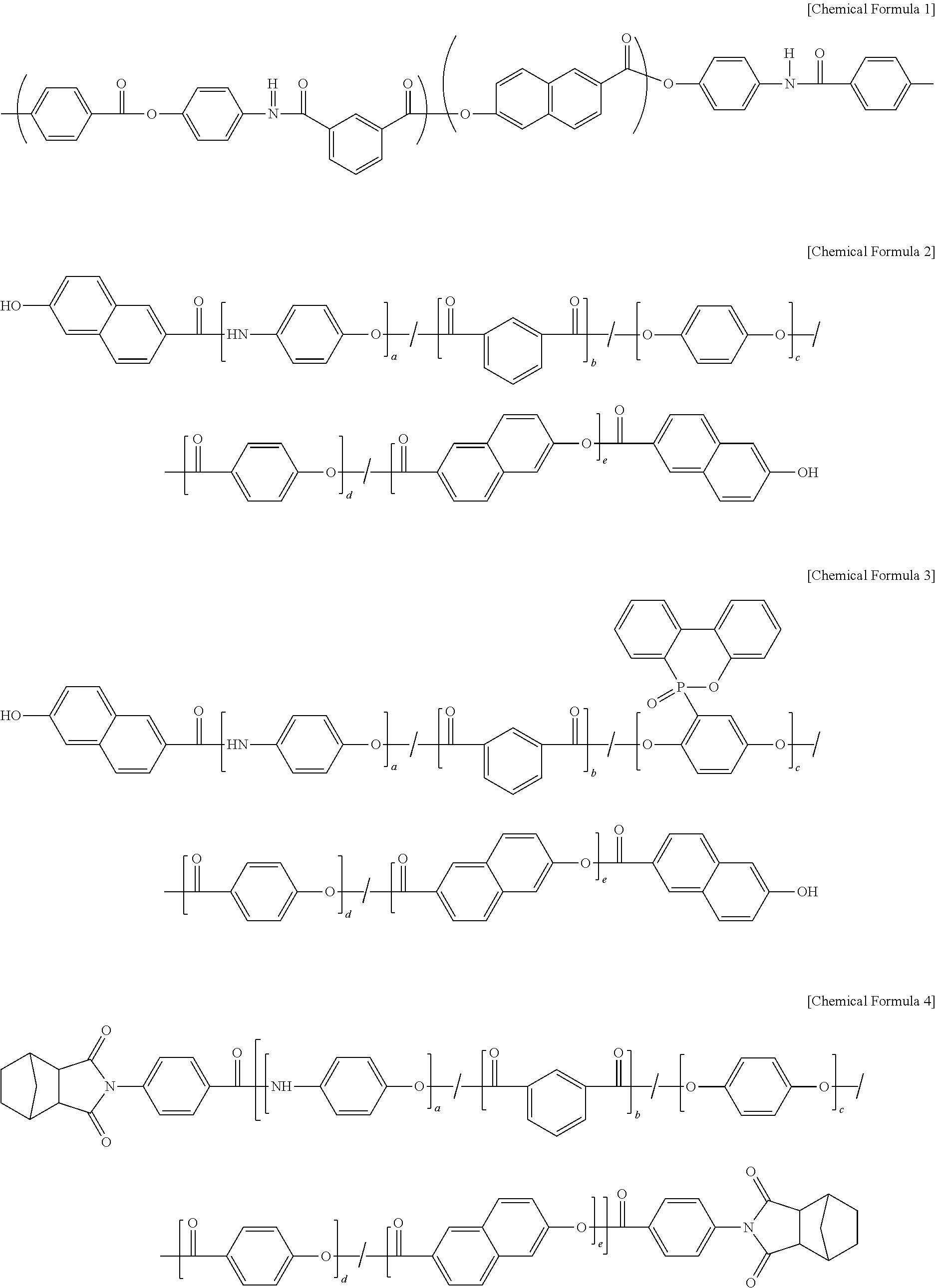

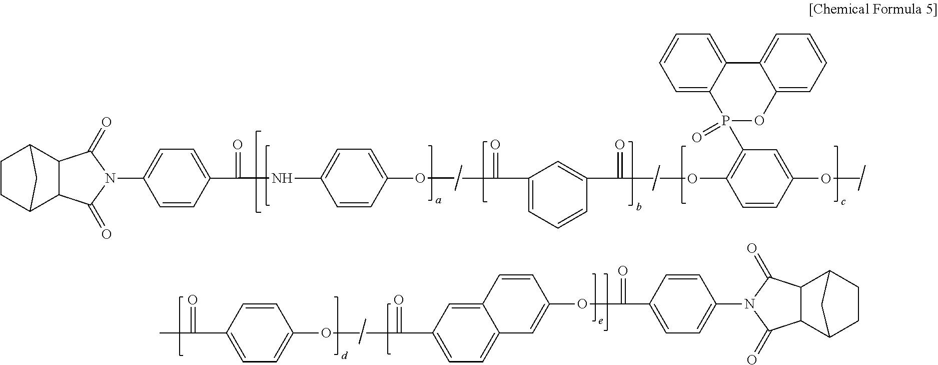

In Chemical Formulas 2 to 5, a is an integer of 13˜26, b is an integer of 13˜26, c is an integer of 9˜21, d is an integer of 10˜30, and e is an integer of 10˜30.

As mentioned above, the amphiphilic block copolymer according to the present invention may form a vertical structure in a thickness direction of the insulating film (i.e. in a direction perpendicular to the surface of a substrate). In particular, a hexagonal structure or a cylinder structure may be formed. Such a vertical structure enables heat generated from the substrate to be effectively emitted via the insulating film, whereas a horizontal structure blocks heat generated from the substrate, making it difficult to effectively emit such heat. In the present invention, the vertical structure does not mean formation of an exact angle of 90° relative to the surface of the substrate, but is to be understood to the extent that effective heat dissipation occurs via the stereostructure of the amphiphilic block copolymer according to the present invention.

A typical example of the amphiphilic block copolymer according to the present invention is represented by Chemical Formula 6 below.

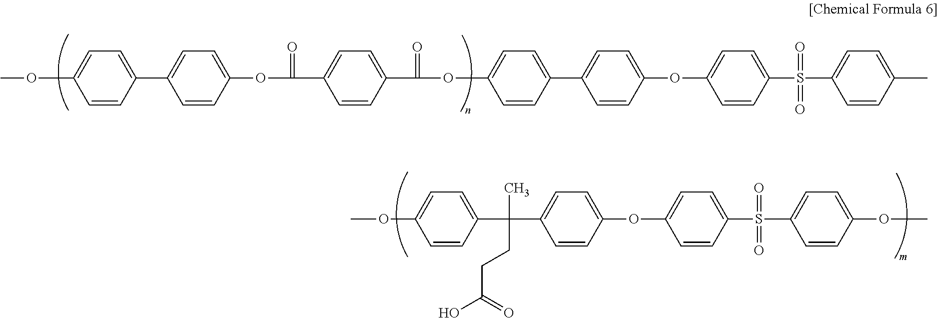

In Chemical Formula 6, n represents a repeating unit of the hydrophobic compound, and m represents a repeating unit of the hydrophilic compound. In Chemical Formula 6, n is an integer of 2˜12, and m is an integer of 6˜48. These numerical values indicate the number of repeating units required to form the amphiphilic block copolymer according to the present invention. If the number of repeating units falls outside of the above ranges, a desired vertical structure cannot be formed.

The insulating film according to the present invention may further include an inorganic filler, an epoxy resin, a curing agent, and/or a curing accelerator, depending on the required properties, in addition to the amphiphilic block copolymer.

For example, the inorganic filler may include one or more selected from the group consisting of silica, alumina, barium sulfate, talc, clay, mica powder, aluminum hydroxide, magnesium hydroxide, calcium carbonate, magnesium carbonate, magnesium oxide, boron nitride, aluminum nitride, aluminum borate, barium titanate, calcium titanate, magnesium titanate, bismuth titanate, titanium oxide, barium zirconate, and calcium zirconate.

The epoxy resin may include one or more selected from the group consisting of a naphthalene-based epoxy resin, a bisphenol A type epoxy resin, a phenol novolac epoxy resin, a cresol novolac epoxy resin, a rubber modified epoxy resin, and a phosphorous epoxy resin.

The curing agent may include one or more selected from the group consisting of an amide-based curing agent, a polyamine-based curing agent, an acid anhydride curing agent, a phenol novolac type curing agent, a polymercaptan curing agent, a tertiary amine curing agent, and an imidazole curing agent.

The curing accelerator may include one or more selected from the group consisting of a metallic curing accelerator, an imidazole-based curing accelerator, and an amine-based curing accelerator.

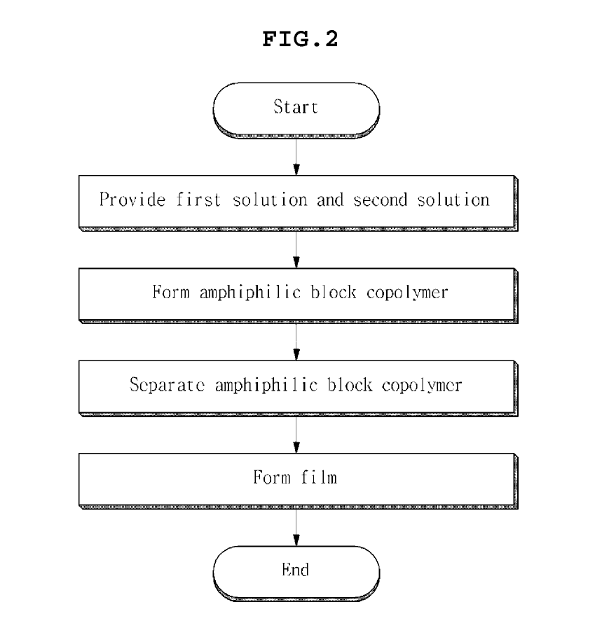

Meanwhile, FIG. 2 illustrates a process of manufacturing the insulating film according to the present invention. As illustrated in FIG. 2, the method of manufacturing the insulating film according to the present invention include dissolving a hydrophilic compound in a solvent and dissolving a hydrophobic compound in a solvent, thus separately preparing a first solution and a second solution. The hydrophilic compound and the hydrophobic compound are mentioned as above, and the solvent is a typical organic solvent. Taking into consideration solubility and miscibility of resin and other additives used in the present invention, examples of the organic solvent may include, but are not particularly limited to, 2-methoxy ethanol, acetone, methylethylketone, cyclohexanone, ethyl acetate, butyl acetate, cellosolve acetate, propylene glycol monomethyl ether acetate, ethylene glycol monobutyl ether acetate, cellosolve, butyl cellosolve, carbitol, butyl carbitol, xylene, dimethylformamide, toluene and dimethylacetamide.

The solvent for the hydrophilic compound may be the same as or different from the solvent for the hydrophobic compound. The hydrophilic compound and the hydrophobic compound may be mixed with the solvent at a weight ratio of about 1:1 in terms of profitability, but the present invention is not limited thereto.

Dissolving the first solution and the second solution may be performed at 120˜180° C. for 10˜15 hr in order to ensure complete and rapid dissolution of the compounds.

Subsequently, the first solution and the second solution are mixed and then reacted. The hydrophilic compound and the hydrophobic compound are chemically coupled with each other, so that an amphiphilic block copolymer is formed in the solution mixture. The reaction may be carried out at 120˜180° C. for 3˜6 hr in consideration of reactivity and profitability. The amphiphilic block copolymer has a vertical structure in a thickness direction when being formed into a film in a subsequent procedure.

The solution mixture including the amphiphilic block copolymer is cooled, and then added to a mixture of alcohol (e.g. ethanol) and distilled water (e.g. deionized water (DIW)), thus forming a precipitate. Thereafter, the amphiphilic block copolymer is recovered, washed with an alcohol, and then dried.

The recovered amphiphilic block copolymer is applied on the shiny surface of a copper foil using, for example, a doctor blade process, thus manufacturing a film. The film is dried at room temperature, dried in a vacuum oven, and then further dried, thus obtaining a semi-cured state (B-stage). The film in which the amphiphilic block copolymer is present in a micelle structure is completely cured using a vacuum press. When the drying and the curing are performed in this way, a desired vertical structure is obtained.

The viscosity of the resin composition including the amphiphilic block copolymer according to the present invention is 700˜1500 cps which is adapted to manufacture a heat dissipation film for electronic devices or an insulating film for printed circuit boards, and this viscosity corresponds to the extent to which appropriate stickiness may be maintained at room temperature. The viscosity of the resin composition may be adjusted by changing the amount of the solvent. The resin composition includes 30˜70 wt % of a nonvolatile component (solid content) except for the solvent. If the viscosity of the resin composition falls outside of the above range, it is difficult to form a heat dissipation film or an insulating film. Even when such a film is formed, it is difficult to form a predetermined member thereon.

The resin composition according to the present invention is incorporated into a base such as glass fibers, and then cured, thus preparing a prepreg, on which a copper foil is then laminated, thereby obtaining CCL (Copper Clad Laminate). Also, the insulating film prepared from the above resin composition may be laminated on the CCL used as an inner layer upon manufacturing a multilayer printed circuit board. For example, an insulating film made of the insulating resin composition is laminated on an inner circuit board having a processed pattern, cured at 80˜110° C. for 20˜30 min, and subjected to desmearing, following by performing an electroplating process, thus forming a circuit layer, resulting in a multilayer printed circuit board.

A better understanding of the present invention may be obtained via the following examples and comparative examples which are set forth to illustrate, but are not to be construed as limiting the present invention.

### Example 1

A 4-neck round bottom flask was equipped with an impeller, a Dean-Stark condenser, a vacuum cock, a bubbler, and a stopper, after which 15.4 g of 4,4′-biphenol (4,4′-BP), and 11.8 g of p-benzenedicarboxylic acid (p-BDCA) were added to dimethylacetylamide (DMAc) and toluene, and then reacted for about 12 hr while toluene was refluxed at about 160° C. Separately, a 4-neck round bottom flask was equipped with an impeller, a Dean-Stark condenser, a vacuum cock, a bubbler, and a stopper, after which 47.4 g of diphenolic acid (DA), 51.0 g of 4,4′-dichlorodiphenylsulfone (DCDPS), and potassium carbonate (K₂CO₃) were added to DMAc and toluene, and then reacted for about 12 hr while toluene was refluxed at about 160° C. These two reaction solutions were cooled to about 60° C. and then mixed, and the resulting solution mixture was then reacted at about 160° C. for about 4 hr. The resulting reaction solution was cooled to room temperature, and then added to a mixture of ethanol and DIW at 8:2, thus forming a precipitate, which was then washed several times using ethanol and dried, thereby obtaining a solid product. The solid product was dissolved in DMAc, added with 66.6 g of bis(N—N-diglycidylaminophenyl)methane (BDGAM) and 0.7 g of dicyandiamide (DiCY), and then applied using an applicator, thus manufacturing a film having a thickness of about 250 μm. This film was cured at about 130° C. for about 1 hr and then at about 230° C. for about 3 hr, yielding an insulating film according to the present invention.

### Comparative Example 1

A 4-neck round bottom flask was equipped with an impeller, a Dean-Stark condenser, a vacuum cock, a bubbler, and a stopper, after which 6.1 g of 4,4′-BP, and 3.7 g of p-BDCA were added to DMAc and toluene, and then reacted for about 12 hr while toluene was refluxed at about 160° C. Separately, a 4-neck round bottom flask was equipped with an impeller, a Dean-Stark condenser, a vacuum cock, a bubbler, and a stopper, after which 56.6 g of DA, 60.0 g of DCDPS, and potassium carbonate (K₂CO₃) were added to DMAc and toluene, and then reacted for about 12 hr while toluene was refluxed at about 160° C. These two reaction solutions were cooled to about 60° C. and then mixed, and the resulting solution mixture was then reacted at about 160° C. for about 4 hr. The resulting reaction solution was cooled to room temperature, and then added to a mixture of ethanol and DIW at 8:2, thus forming a precipitate, which was then washed several times using ethanol and dried, thereby obtaining a solid product. The solid product was dissolved in DMAc, added with 66.6 g of BDGAM and 0.7 g of DiCY, and then applied using an applicator, thus manufacturing a film having a thickness of about 250 μm. This film was cured at about 130° C. for about 1 hr and then at about 230° C. for about 3 hr, yielding an insulating film according to the present invention.

### Comparative Example 2

An insulating film was manufactured in the same manner under the same conditions as in Comparative Example 1, with the exception that 26.4 g of 4,4′-BP, 21.4 g of p-BDCA, 36.9 g of DA, and 40.7 g of DCDPS were added.

### Comparative Example 3

An insulating film was manufactured in the same manner under the same conditions as in Comparative Example 1, with the exception that 39 g of 4,4′-BP, 32.5 g of p-BDCA, 24 g of DA, and 28.1 g of DCDPS were added.

[Measurement of Thermal Conductivity]

The thermal conductivity of the insulating film according to the present invention was evaluated as follows.

According to the present invention, the amphiphilic block copolymers were synthesized at different mole ratios of the hydrophilic compound (DA, DCDPS) and the hydrophobic compound (4,4′-BP, p-BDCA), and the thermal conductivity (K) of the insulating films formed therefrom was evaluated. The results are shown in Table 1 below.

The thermal conductivity may be measured using Equation 1 below.

K=Cp×ρ×α [Equation 1]

K: thermal conductivity

Cp: heat capacity

ρ: density)

α: thermal diffusivity

The manufactured film was made in the form of a 0.5-inch disc, after which thermal diffusivity (α) was measured using LFA447 model available from Netsch, heat capacity (Cp) was measured based on a sapphire standard using Q100 model DSC available from TA, and density (ρ) was measured using Archimedes principle.

TABLE 1

| | 4,4′-BP(g) | p-BDCA(g) | DA(g) | DCDPS(g) | BDGAM(g) | DiCY(g) | K (W/m · K) |
|---|---|---|---|---|---|---|---|
| Ex. 1 | 15.4 | 11.8 | 47.4 | 51 | 66.6 | 0.7 | 0.44 |
| Comp. Ex. 1 | 6.1 | 3.7 | 56.6 | 60.0 | 66.6 | 0.7 | 0.21 |
| Comp. Ex. 2 | 26.4 | 21.4 | 36.9 | 40.7 | 66.6 | 0.7 | 0.26 |
| Comp. Ex. 3 | 39 | 32.5 | 24 | 28.1 | 66.6 | 0.7 | 0.31 |

| | | | | |
|---|---|---|---|---|
| Comp. Ex. 4 | self-developed LCO 100 g | 66.6 | 0.7 | 0.34 |

As is apparent from Table 1, in Example 1 in which the mole ratio of the hydrophobic compound and the hydrophilic compound is adjusted to 3:7, the amphiphilic block copolymer forms a cylinder vertical structure, ultimately improving thermal conductivity. On the other hand, as seen in Table 1, in Comparative Examples 1 to 3 in which the mole ratio of the hydrophobic compound and the hydrophilic compound is adjusted to 1:9, 5:5, and 7:3, low thermal conductivity values of 0.21, 0.26, and 0.31, respectively, are obtained. In Comparative Example 4 using only 100 g of the liquid crystal polymer instead of the amphiphilic block copolymer of the invention, comparatively high thermal conductivity of 0.34 is obtained because of high thermal conductivity of the liquid crystal polymer.

Consequently, in the case where the mole ratio of the hydrophilic compound and the hydrophobic compound according to the present invention falls in the range of 1.5˜4:1, higher thermal conductivity can be obtained, compared to when using the liquid crystal polymer having high thermal conductivity.

As described hereinbefore, the present invention provides an insulating film for a printed circuit board having improved thermal conductivity, a manufacturing method thereof, and a printed circuit board using the same. According to the present invention, the insulating film is configured such that the stereostructure of the polymer for the film is formed in a vertical direction (i.e. a thickness direction of the insulating film), thus effectively transferring heat. Thereby, the insulating film having superior heat dissipation performance, and the printed circuit board including the same can be provided.

Although the embodiments of the present invention have been disclosed for illustrative purposes, those skilled in the art will appreciate that a variety of different modifications, additions and substitutions are possible, without departing from the scope and spirit of the invention as disclosed in the accompanying claims.

Accordingly, such modifications, additions and substitutions should also be understood as falling within the scope of the present invention.

What is claimed is:

1. An insulating film for a printed circuit board having improved thermal conductivity, which is manufactured from a resin composition comprising an amphiphilic block copolymer having a vertical structure formed in a thickness direction by chemically coupling a hydrophilic compound with a hydrophobic compound.

2. The insulating film of claim 1, wherein the hydrophilic compound and the hydrophobic compound are coupled at a mole ratio of 1.5˜4:1.

3. The insulating film of claim 1, wherein the hydrophilic compound is an epoxy group-containing compound.

4. The insulating film of claim 1, wherein the hydrophobic compound is a liquid crystal polymer.

5. The insulating film of claim 4, wherein the liquid crystal polymer is represented by Chemical Formula 1, Chemical Formula 2, Chemical Formula 3, Chemical Formula 4 or Chemical Formula 5 below. 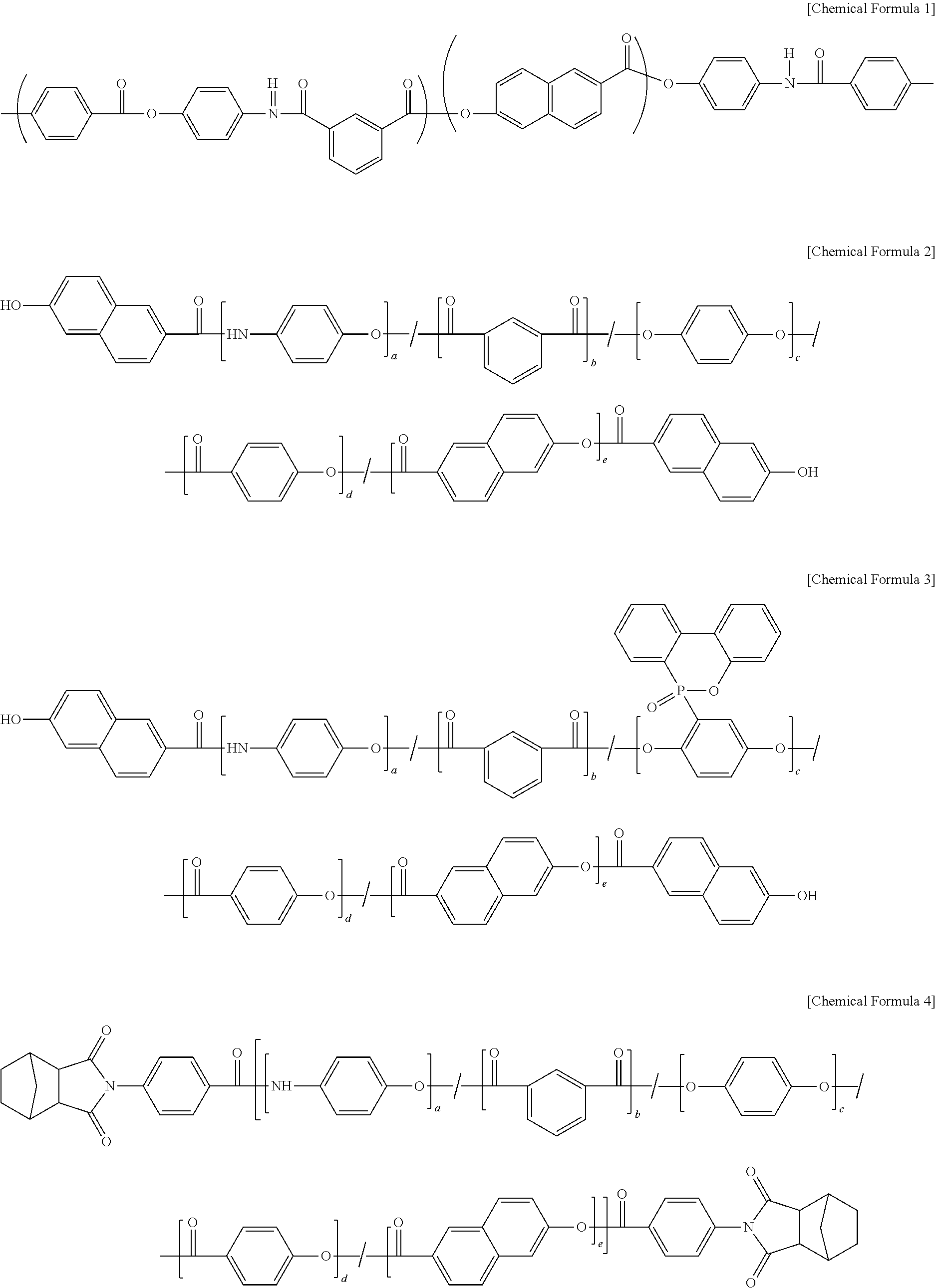 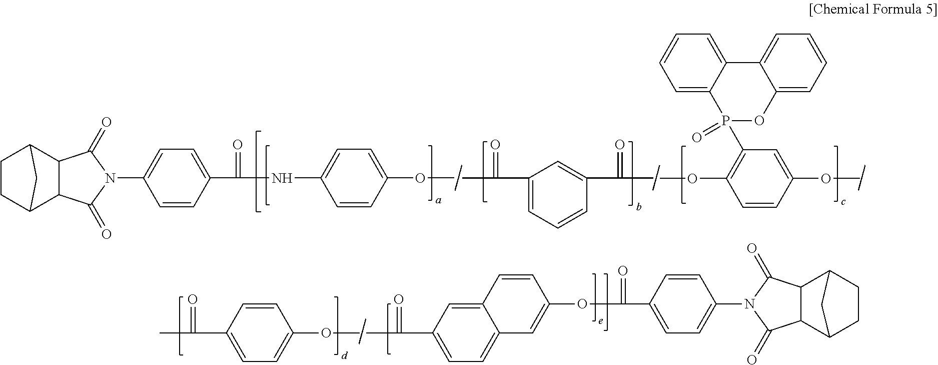
wherein a is an integer of 13˜26, b is an integer of 13˜26, c is an integer of 9˜21, d is an integer of 10˜30, and e is an integer of 10˜30.

6. The insulating film of claim 1, wherein the vertical structure is a hexagonal structure or a cylinder structure.

7. The insulating film of claim 1, wherein the amphiphilic block copolymer is a compound represented by Chemical Formula 6 below. 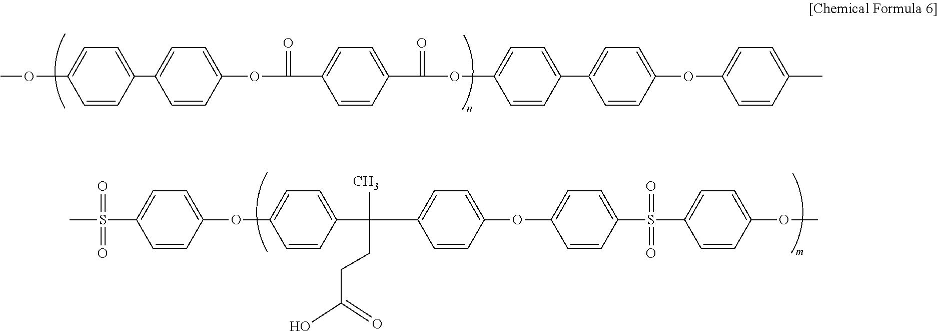
wherein n is an integer of 2˜12, and m is an integer of 6˜48.

8. The insulating film of claim 1, wherein the insulating film further comprises an inorganic filler comprising one or more selected from the group consisting of silica, alumina, barium sulfate, talc, clay, mica powder, aluminum hydroxide, magnesium hydroxide, calcium carbonate, magnesium carbonate, magnesium oxide, boron nitride, aluminum nitride, aluminum borate, barium titanate, calcium titanate, magnesium titanate, bismuth titanate, titanium oxide, barium zirconate, and calcium zirconate.

9. The insulating film of claim 1, wherein the insulating film further comprises an epoxy resin comprising one or more selected from the group consisting of a naphthalene-based epoxy resin, a bisphenol A type epoxy resin, a phenol novolac epoxy resin, a cresol novolac epoxy resin, a rubber modified epoxy resin, and a phosphorous epoxy resin.

10. The insulating film of claim 1, wherein the insulating film further comprises a curing agent comprising one or more selected from the group consisting of an amide-based curing agent, a polyamine-based curing agent, an acid anhydride curing agent, a phenol novolac type curing agent, a polymercaptan curing agent, a tertiary amine curing agent, and an imidazole curing agent.

11. The insulating film of claim 1, wherein the insulating film further comprises a curing accelerator comprising one or more selected from the group consisting of a metallic curing accelerator, an imidazole-based curing accelerator, and an amine-based curing accelerator.

12. A method of manufacturing an insulating film for a printed circuit board, comprising:
dissolving a hydrophilic compound in a solvent thus providing a first solution, and dissolving a hydrophobic compound in a solvent, thus providing a second solution;
mixing the first solution with the second solution so as to react, thus forming an amphiphilic block copolymer having a vertical structure formed in a thickness direction by chemically coupling the hydrophilic compound with the hydrophobic compound;
recovering the amphiphilic block copolymer; and
forming a film using the recovered amphiphilic block copolymer.

13. The method of claim 12, wherein the vertical structure is a hexagonal structure or a cylinder structure.

14. The method of claim 12, wherein the amphiphilic block copolymer is a compound represented by Chemical Formula 6 below. 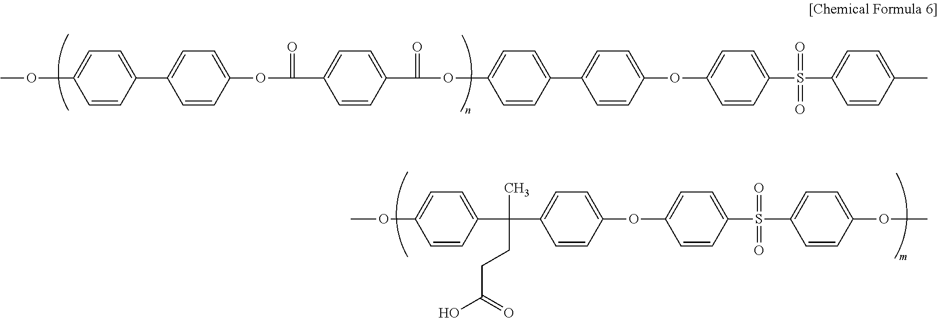
wherein n is an integer of 2˜12, and m is an integer of 6˜48.

15. The method of claim 12, wherein the hydrophilic compound and the hydrophobic compound are coupled at a mole ratio of 1.5˜4:1.

16. The method of claim 12, wherein the hydrophilic compound is an epoxy group-containing compound.

17. The method of claim 12, wherein the hydrophobic compound is a liquid crystal polymer.

18. A printed circuit board using the insulating film of claim 1.
